(19) United States
(12) Patent Application Publication
(10) Pub. No.: US 2017/0202116 A1
(43) Pub. Date: Jul. 13, 2017

(54) METHOD FOR REDUCING GAP IN GASKET FILLING

(71) Applicant: TennVac Inc., New Taipei City (TW)

(72) Inventor: Pai-Lee CHANG, New Taipei City (TW)

(73) Assignee: TennVac Inc.

(21) Appl. No.: 15/089,673

(22) Filed: Apr. 4, 2016

(30) Foreign Application Priority Data
Jan. 13, 2016 (CN) 201610021124.7

(51) Int. Cl. H05K 9/00; H05K 5/06; F16J 15/06

(52) U.S. Cl. CPC H05K 9/0081; F16J 15/064; H05K 5/061; F16J 15/061

(57) ABSTRACT

The present invention provides a method for reducing gap in gasket filling, comprising the steps of: providing a structure; forming a fillet; and performing gasket filling, wherein, the fillet in a round corner form is formed at the starting point or the end point of the gasket filling path. With the present invention, the gasket filled at the two ends of the gasket filling path, namely the starting point and the end point of the gasket filling path, would not form a gap between the gasket and the structure, can effectively prevent water or debris from entering into the structure, and when the gasket used is a conductive gasket, electro-magnetic interference (EMI) is perfectly shielded from entering into or radiating out of the structure.

### BACKGROUND OF THE INVENTION

1. Technical Field

The present invention relates to a gasket filling method, and particularly relates to a method for reducing gap in gasket filling by forming a fillet and thus reducing the gaps formed during gasket filling.

2. Description of Related Art

In modern life with electronic products becoming more and more widespread, the beneficial and harmful characteristics of these products such as their functions, durability, and the harm against human body greatly determines their packaging and gluing qualities.

As shown in FIG. 1, assembly of electronic product structure 200 is commonly joined by gasket 400, and therefore no matter the bonding level of the gasket 400 is good or bad, due to the cohesive characteristic of the substance molecules, the two ends of the gasket 400 condense into an arc shape. As a result, a gap 300 is formed between any of the two ends of the gasket 400 and the structure 200. Since it is extremely hard to control the size of the gap 300, formation of the gap 300 would even cause failure of the whole product or render the product inadequate to meet safety regulation requirements.

In other words, formation of such a gap 300 not only allows water, dust, or other foreign substances to enter into the already assembled structure 200 easily, but also undermines its intended purpose of achieving dustproof and waterproof functions, and greatly shortens the expected life of the electronic product.

Furthermore, if the intended purpose of gasket 400 is to provide electro-magnetic interference (EMI) isolation during use, a gap 300 can possibly cause EMI leakage, which not only renders the electronic product inadequate to meet the safety regulation requirements, but also in a good possibility to cause unwanted harm on human body.

In view of these, the purpose of the invention is to improve the above said deficiencies in assembly of the prior art electronic product structures 200, prevent formation of a gap 300 between the gasket 400 and the structure 200 during the gasket filling process in production of electronic products, or minimize the formed gap 300 in order to prevent intrusion of moisture or foreign substances, and even prevent formation of EMI leakage, and thus provide a significant improvement in electronic industry and in various areas of usage, and as a result, contribute significantly to the improvement of people's quality of life.

### SUMMARY OF THE INVENTION

The present invention relates to a method for reducing gap in gasket filling, comprising the steps of: providing a structure; forming a fillet; and performing gasket filling, wherein, the fillet is formed at the starting point or the end point of the gasket filling path. With the present invention, the gasket filled at the two ends of the gasket filling path, namely the starting point and the end point of the gasket filling path, would not form a gap between the gasket and the structure, can effectively prevent water or impurities from entering into the structure, and if the gasket used is a conductive gasket, it can also prevent electro-magnetic interference (EMI) from entering into or radiating out of the structure.

The present invention provides a method for reducing gap in gasket filling, comprising the steps of: providing a structure, comprising at least one gasket filling path; forming a fillet, which is forming a round corner at the starting point or the end point of the gasket filling path; and performing gasket filling, wherein the gasket are filled from the starting point to the end point through the gasket filling path.

Implementation of the present invention at least involves the following inventive steps:

1. Complicated manufacturing processes or manufacturing equipment won't be required, and thus cost of implementation will be reduced.

2. Waterproof and dustproof characteristics will be obtained.

3. Electro-magnetic interference will be prevented from entering through the gap or being radiated from the structure.

The features and advantages of the present invention are detailed hereinafter with reference to the preferred examples. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE SEVERAL VIEWS OF THE DRAWINGS

The invention as well as a preferred mode of use, further objectives and advantages thereof will be best understood by reference to the following detailed description of illustrative examples when read in conjunction with the accompanying drawings, wherein:

FIG. 1 (PRIOR ART) is a schematic view of a conventional gasket method that suffers a gap in between the gasket and the structure.

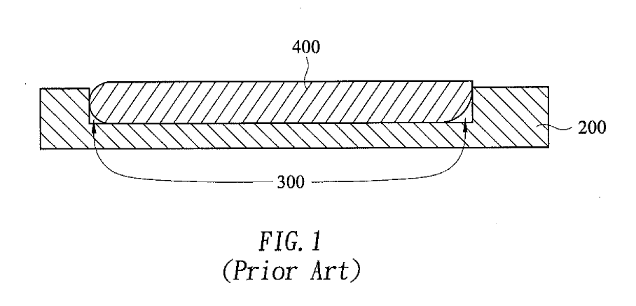

FIG. 2 is a process flow chart of a method for reducing gap in gasket filling in an example of the present invention.

FIG. 3A is a three dimensional schematic view of a structure having a gasket filling path in an example of the present invention.

FIG. 3B is a three dimensional schematic view of another structure having a gasket filling path in an example of the present invention.

FIG. 4 is a schematic view of filling gasket into the gasket filling path comprising a fillet.

### DETAILED DESCRIPTION OF THE EXAMPLES OF THE INVENTION

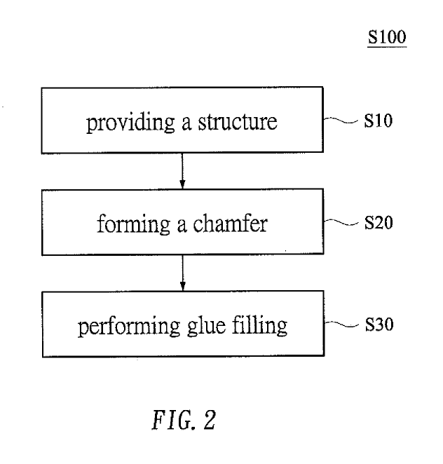

Referring to FIG. 2, in an example, a method is provided for reducing gap in gasket filling S100, comprising the steps of: providing a structure (step S10); forming a fillet (step S20); and performing gasket filling (step S30).

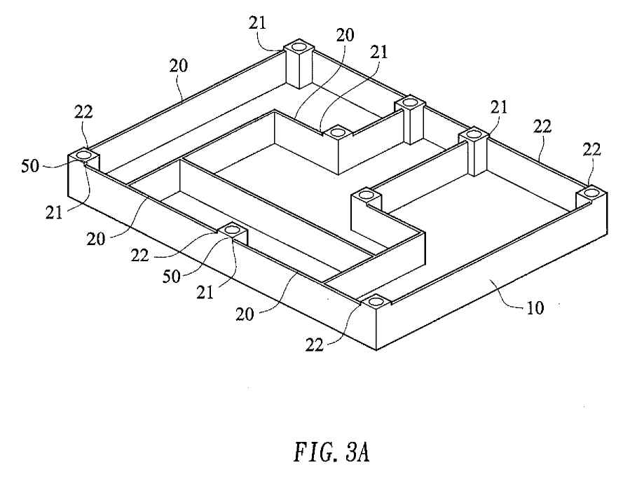

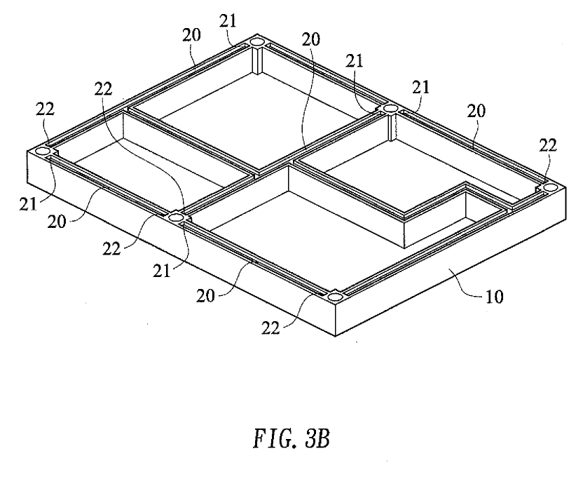

Referring to FIGS. 2, 3A, and 3B, in providing a structure (step S10), the structure 10 is usually a shell of an electronic product or a part thereof, which can be manufactured by moulding, CNC processing, injection moulding, or another method.

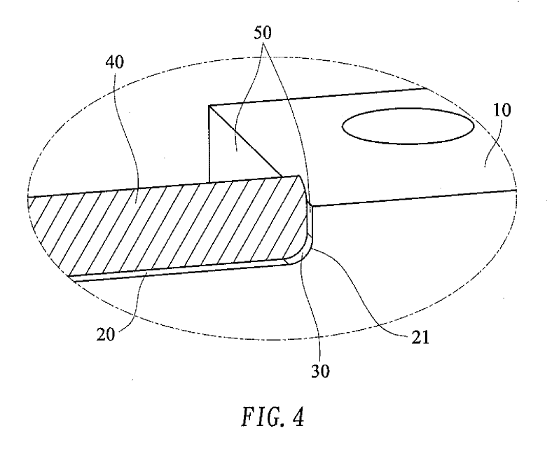

Referring to FIGS. 2 to 4, at least one gasket filling path 20 is found on the structure 10, wherein each gasket filling path 20 also comprises a starting point 21 and an end point 22.

Referring to FIGS. 3A and 3B, the gasket filling path 20 can be flat, can have a lower or higher elevation difference, or the gasket filling path 20 can even be a groove. Also, the gasket filling path 20 can be coupled to a raised surface 50 higher than the gasket filling path 20 at the starting point 21 or the end point 22.

The position, length, and thickness of the gasket filling path 20 are determined according to different uses and demands and cannot be limited specifically. In practical use, the width of the gasket filling path 20 can be selected as not to be greater than 0.3 mm; or the width of the gasket filling path 20 can be smaller than 0.5 mm; or the width of the gasket filling path 20 can be between 0.5 mm and 2 mm.

Referring to FIGS. 2 to 4 again, in forming the fillet (step S20), a fillet 30, that is a shape with a round corner, is formed at the starting point 21 or the end point 22 of the gasket filling path 20. The formed fillet 30 can be an arc or a bevel edge (hypotenuse) chamfer, or even an edge that is formed by various consecutive bevel edges with different angles.

Referring to FIGS. 2 to 4, in performing the gasket filling (step S30), a gasket 40 is filled through the gasket filling path 20 from the starting point 21 to the end point 22. The step of performing gasket filling (step S30) can be performed by an automatic gasket filling machine, and the characteristics of the filled gasket 40 can be chosen among different options according to the application requirements.

Filled gasket 40 not only protects the structure 10 from intrusion of water/moisture, impurities, or foreign substances from a gap or gaps between the structure 10 and the gasket 40, but also, if a conductive gasket 40 is chosen, after gluing the structure 10, it can effectively prevent leakage of electro-magnetic interference (EMI), and thus prevent electro-magnetic interference from entering into the structure 10 through the gluing location or being radiated out from the structure 10.

In summary, as disclosed in each example, the gasket 40 filled at the two ends of the gasket filling path 20, namely the starting point 21 and the end point 22 of the gasket filling path 20, would not form a gap between the gasket 40 and the structure 10 due to the cohesiveness of the gasket 40 itself or any other factor, and can effectively prevent water, foreign substances, or impurities from entering into the structure 10, or prevent electro-magnetic interference (EMI) from entering into or radiating out of the structure 10.

Moreover, the method for reducing gap in gasket filling S100 does not require a complicated manufacturing process or manufacturing equipment, has low cost of implementation and manufacturing, and can be extensively and sufficiently used in various kinds of products of all sizes.

The examples described above are intended only to demonstrate the technical concept and features of the present invention so as to enable a person skilled in the art to understand and implement the contents disclosed herein. It is understood that the disclosed examples are not to limit the scope of the present invention. Therefore, all equivalent changes or modifications based on the concept of the present invention should be encompassed by the appended claims.

What is claimed is:

1. A method for reducing gap in gasket filling, comprising the steps of:
providing a structure, which comprising at least one gasket filling path;
forming a fillet, which is forming a round corner at the starting point or the end point of the gasket filling path; and
performing gasket filling, wherein the gasket are filled from the starting point to the end point through the gasket filling path.

2. The method for reducing gap in gasket filling according to claim 1, wherein the gasket filling path is formed on the structure in a groove.

3. The method for reducing gap in gasket filling according to claim 1, wherein the structure is a CNC processed structure.

4. The method for reducing gap in gasket filling according to claim 1, wherein the fillet is with a round corner.

5. The method for reducing gap in gasket filling according to claim 1, wherein the fillet is a bevel edge (hypotenuse) chamfer.

6. The method for reducing gap in gasket filling according to claim 1, wherein the gasket is a conductive gasket.

7. The method for reducing gap in gasket filling according to claim 1, wherein the step of performing gasket filling is performed by an automatic gasket filling machine.

8. The method for reducing gap in gasket filling according to claim 1, wherein the width of the gasket filling path is not greater than 0.3 mm.

9. The method for reducing gap in gasket filling according to claim 1, wherein the width of the gasket filling path is smaller than 0.5 mm.

10. The method for reducing gap in gasket filling according to claim 1, wherein the width of the gasket filling path is between 0.5 mm and 2 mm.
